(19) United States
(12) Patent Application Publication
(10) Pub. No.: US 2026/0025102 A1
(43) Pub. Date: Jan. 22, 2026

(54) VOLTAGE SWITCHING IN A POWER MANAGEMENT INTEGRATED CIRCUIT

(71) Applicant: Qorvo US, Inc., Greensboro, NC (US)

(72) Inventors: Nadim Khlat, Cugnaux (FR); Robert Moehrke, Winston-Salem, NC (US)

(21) Appl. No.: 18/996,017

(22) PCT Filed: Jul. 17, 2023
(86) PCT No.: PCT/US2023/027865

§ 371 Date: Jan. 17, 2025

Related U.S. Application Data
(60) Provisional application No. 63/401,785, filed on Aug. 29, 2022.
(60) Provisional application No. 63/480,796, filed on Jan. 20, 2023.

(51) Int. Cl. H03F 1/02; H03F 3/24

(52) U.S. Cl. CPC H03F 1/02; H03F 3/245; H03F 2200/451; H03F 2200/511

(57) ABSTRACT

Voltage switching in a power management integrated circuit (PMIC) is provided. The PMIC is required to increase or decrease a modulated voltage from a present voltage level in a present one of multiple time intervals to a future voltage level in an upcoming one of the time intervals with a very short switching interval. Herein, the PMIC determines whether to change the modulated voltage based on a first voltage transition scheme or a second voltage transition scheme, and toggle between the first voltage transition scheme and the second voltage transition scheme dynamically from one time interval to another. By employing the first voltage transition scheme or the second voltage transition scheme, the PMIC can switch the modulated voltage in a timely manner. Further, by opportunistically employing the first voltage transition scheme whenever possible, the PMIC can also help reduce potential power loss associated with switching the modulated voltage.

### RELATED APPLICATIONS

This application claims the benefit of U.S. provisional patent application Ser. No. 63/401,785, filed on Aug. 29, 2022, and the benefit of U.S. provisional patent application Ser. No. 63/480,796, filed on Jan. 20, 2023, the disclosures of which are hereby incorporated herein by reference in their entireties.

### FIELD OF THE DISCLOSURE

The technology of the disclosure relates generally to a power management integrated circuit (PMIC).

### BACKGROUND

Fifth generation (5G) new radio (NR) (5G-NR) has been widely regarded as the next generation of wireless communication technology beyond the current third generation (3G) and fourth generation (4G) technologies. In this regard, a wireless communication device capable of supporting the 5G-NR wireless communication technology is expected to achieve higher data rates, improved coverage range, enhanced signaling efficiency, and reduced latency.

Downlink and uplink transmissions in a 5G-NR system are widely based on orthogonal frequency division multiplexing (OFDM) technology. In an OFDM based system, physical radio resources are divided into a number of subcarriers in a frequency domain and a number of OFDM symbols in a time domain. The subcarriers are orthogonally separated from each other by a subcarrier spacing (SCS). The OFDM symbols are separated from each other by a cyclic prefix (CP), which acts as a guard band to help overcome inter-symbol interference (ISI) between the OFDM symbols.

A radio frequency (RF) signal communicated in the OFDM based system is often modulated into multiple subcarriers in the frequency domain and multiple OFDM symbols in the time domain. The multiple subcarriers occupied by the RF signal collectively define a modulation bandwidth of the RF signal. The multiple OFDM symbols, on the other hand, define multiple time intervals during which the RF signal is communicated. In the 5G-NR system, the RF signal is typically modulated with a high modulation bandwidth in excess of 200 MHz.

The duration of an OFDM symbol depends on the SCS and the modulation bandwidth. The table below (Table 1) provides some OFDM symbol durations, as defined by 3G partnership project (3GPP) standards for various SCSs and modulation bandwidths. Notably, the higher the modulation bandwidth is, the shorter the OFDM symbol duration will be. For example, when the SCS is 120 KHz and the modulation bandwidth is 400 MHz, the OFDM symbol duration is 8.93 μs.

TABLE 1

| | | | | OFDM | |
|---|---|---|---|---|---|
| | Slot | # of Slots | | Symbol | Modulation |
| SCS | Length | per | CP | Duration | Bandwidth |
| (KHz) | (μs) | Subframe | (μs) | (μs) | (MHz) |
| 15 | 1000 | 1 | 4.69 | 71.43 | 50 |
| 30 | 500 | 2 | 2.34 | 35.71 | 100 |
| 60 | 250 | 4 | 1.17 | 17.86 | 200 |
| 120 | 125 | 8 | 0.59 | 8.93 | 400 |

In a 5G-NR system, the RF signal can be modulated with a time-variant power that changes from one OFDM symbol to another. In this regard, a power amplifier circuit(s) is required to amplify the RF signal to a certain power level within each OFDM symbol duration. Such inter-symbol power variation creates a unique challenge for a power management integrated circuit (PMIC) because the PMIC must be able to adapt a modulated voltage supplied to the power amplifier circuit within the CP of each OFDM symbol to help avoid distortion (e.g., amplitude clipping) in the RF signal.

### SUMMARY

Embodiments of the disclosure relate to voltage switching in a power management integrated circuit (PMIC). The PMIC is required to increase or decrease a modulated voltage from a present voltage level in a present one of multiple time intervals to a future voltage level in an upcoming one of the time intervals with a very short switching interval (e.g., <20 nanoseconds). Herein, the PMIC can determine whether to change the modulated voltage based on a first voltage transition scheme or a second voltage transition scheme, and toggle between the first voltage transition scheme and the second voltage transition scheme dynamically from one time interval to another. By changing the modulated voltage based on the first voltage transition scheme or the second voltage transition scheme, the PMIC can switch the modulated voltage from the present voltage level to the future voltage level in a timely manner. Further, by opportunistically employing the first voltage transition scheme whenever possible, the PMIC can also help reduce potential power loss associated with switching the modulated voltage.

In one aspect, a PMIC is provided. The PMIC includes a voltage output that outputs a modulated voltage to a power amplifier circuit for amplifying an RF signal modulated in multiple time intervals. The PMIC also includes a voltage processing circuit. The voltage processing circuit is configured to generate the modulated voltage at a respective voltage level in each of the multiple time intervals. The PMIC also includes a control circuit. The control circuit is configured to receive a modulated target voltage indicating that the modulated voltage needs to transition from a present voltage level in a present time interval among the multiple time intervals to a future voltage level in an upcoming time interval immediately succeeding the present time interval among the multiple time intervals. The control circuit is also configured to control the voltage processing circuit to change the modulated voltage from the present voltage level to the future voltage level based on one of a first voltage transition scheme and a second voltage transition scheme.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary wireless communication circuit wherein a power management integrated circuit (PMIC) is configured according to embodiments of the present disclosure to change a modulated voltage based on a first voltage transition scheme or a second voltage transition scheme;

FIG. 2A is a flowchart of an exemplary process that can be employed by the PMIC in FIG. 1 to change the modulated voltage;

FIG. 2B is a flowchart of an exemplary process whereby the PMIC in FIG. 1 can determine whether to change the modulated voltage based on the first voltage transition scheme or the second voltage transition scheme;

FIG. 3 is a timing diagram providing an exemplary illustration of the PMIC in FIG. 1 configured according to an embodiment of the present disclosure to increase the modulated voltage from a present voltage level to a future voltage level based on the first voltage transition scheme;

FIG. 4 is a timing diagram providing an exemplary illustration of the PMIC in FIG. 1 configured according to an embodiment of the present disclosure to decrease the modulated voltage from a present voltage level to a future voltage level based on the first voltage transition scheme;

FIG. 5 is a timing diagram providing an exemplary illustration of the PMIC in FIG. 1 configured according to an embodiment of the present disclosure to increase the modulated voltage from a present voltage level to a future voltage level based on the second voltage transition scheme;

FIG. 6 is a timing diagram providing an exemplary illustration of the PMIC in FIG. 1 configured according to an embodiment of the present disclosure to decrease the modulated voltage from a present voltage level to a future voltage level based on the second voltage transition scheme;

FIG. 7 is a timing diagram providing an exemplary illustration of the PMIC in FIG. 1 configured according to another embodiment of the present disclosure to decrease the modulated voltage from a present voltage level to a future voltage level based on the second voltage transition scheme; and

FIG. 8 is a schematic diagram of an exemplary user element wherein the wireless communication circuit of FIG. 1 can be provided.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to voltage switching in a power management integrated circuit (PMIC). The PMIC is required to increase or decrease a modulated voltage from a present voltage level in a present one of multiple time intervals to a future voltage level in an upcoming one of the time intervals with a very short switching interval (e.g., <20 nanoseconds). Herein, the PMIC can determine whether to change the modulated voltage based on a first voltage transition scheme or a second voltage transition scheme, and toggle between the first voltage transition scheme and the second voltage transition scheme dynamically from one time interval to another. By changing the modulated voltage based on the first voltage transition scheme or the second voltage transition scheme, the PMIC can switch the modulated voltage from the present voltage level to the future voltage level in a timely manner. Further, by opportunistically employing the first voltage transition scheme whenever possible, the PMIC can also help reduce potential power loss associated with switching the modulated voltage.

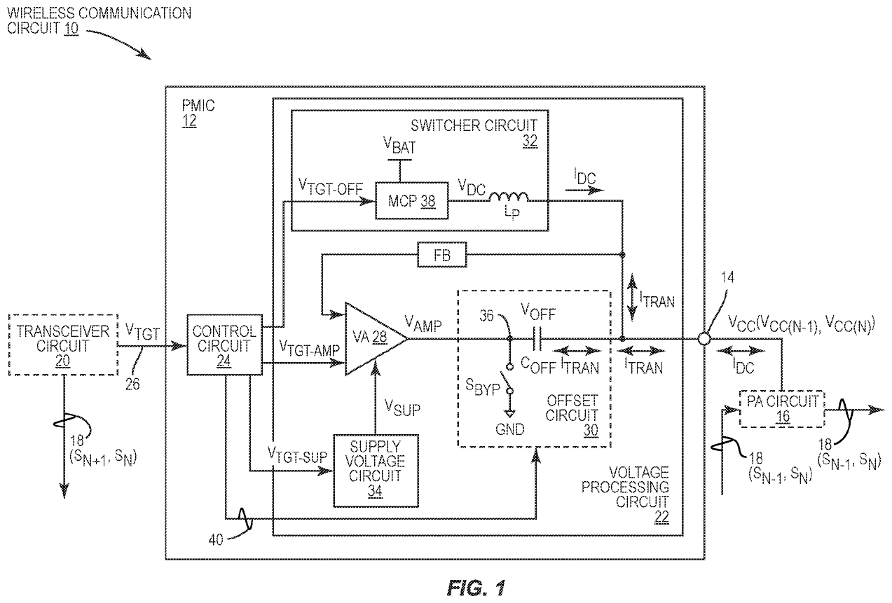

In this regard, FIG. 1 is a schematic diagram of an exemplary wireless communication circuit 10 wherein a PMIC 12 is configured according to embodiments of the present disclosure to change a modulated voltage V_{CC} based on a first voltage transition scheme or a second voltage transition scheme. The PMIC 12 includes a voltage output 14 that outputs the modulated voltage V_{CC} to a power amplifier circuit 16. The power amplifier circuit 16 is configured to amplify a radio frequency (RF) signal 18 based on the modulated voltage V_{CC}.

The RF signal 18, which may be generated by a transceiver circuit 20, is modulated in multiple time intervals. For the sake of reference and illustration, the time intervals are represented hereinafter by a pair of adjacent time intervals S_{N-1}, S_{N}, wherein S_{N} immediately succeeds S_{N-1}. Understandably, the RF signal 18 can be modulated in an infinite number of continuous time intervals.

In the context of the present disclosure, each of the time intervals S_{N-1}, S_{N} can be an orthogonal frequency division multiplexing (OFDM) symbol. In this regard, each of the time intervals S_{N-1}, S_{N} can be modulated to carry a data payload (referred herein as “a data symbol”) and a reference signal (referred herein as “a reference symbol”), such as a demodulation reference signal (DMRS), a sounding reference signal (SRS), and so on.

Given that the power amplifier circuit 16 needs to amplify the data symbols and the reference symbols to different power levels, the PMIC 12 needs to adapt (increase or decrease) the modulated voltage V_{CC} on a per-symbol basis. Moreover, as mentioned earlier, the PMIC 12 must change the modulated voltage V_{CC} from one voltage level to another within the respective cyclic prefix (CP) in each of the OFDM symbols S_{N-1}, S_{N}.

The PMIC 12 includes a voltage processing circuit 22 that is coupled to the voltage output 14. The voltage processing circuit 22 is configured to generate the modulated voltage V_{CC} at a respective voltage level in each of the time intervals S_{N-1}, S_{N}.

The PMIC 12 also includes a control circuit 24, which can be a field-programmable gate array (FPGA), an application-specific integrated circuit (ASIC), or a microprocessor, as an example. Herein, the control circuit 24 is configured to receive a modulated target voltage V_{TGT} from the transceiver circuit 20. In a non-limiting example, the control circuit 24 can receive the modulated voltage V_{TGT} via an RF frontend (RFFE) bus 26.

The modulated target voltage V_{TGT} is so generated to indicate whether the modulated voltage V_{CC} needs to transition (increase, decrease, or remain unchanged) from a present voltage level (denoted as “V_{CC(N-1)}”) in the time interval S_{N-1} (a.k.a. “present time interval”) to a future voltage level (denoted as “V_{CC(N)}”) in the time interval S_{N} (a.k.a. “upcoming time interval immediately succeeding the present time interval”).

According to various embodiments of the present disclosure, the control circuit 24 is further configured to dynamically determine whether the modulated voltage V_{CC} should be changed according to a first voltage transition scheme or a second voltage transition scheme. Accordingly, the control circuit 24 can control the voltage processing circuit 22 to change the modulated voltage V_{CC} from the present voltage level V_{CC(N-1)} to the future voltage level V_{CC(N)} based on the determined one of the first voltage transition scheme and the second voltage transition scheme.

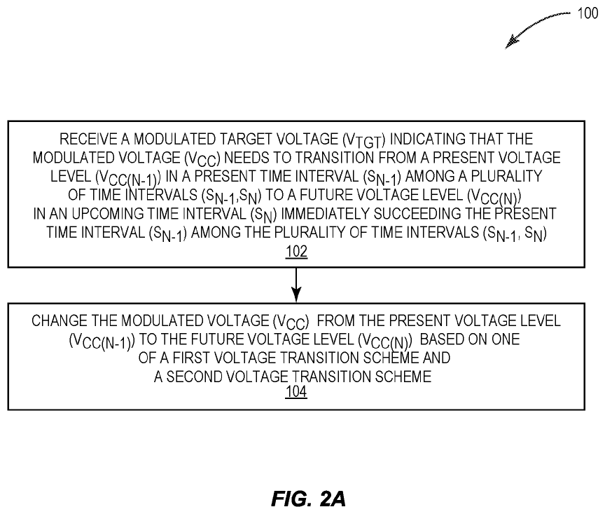

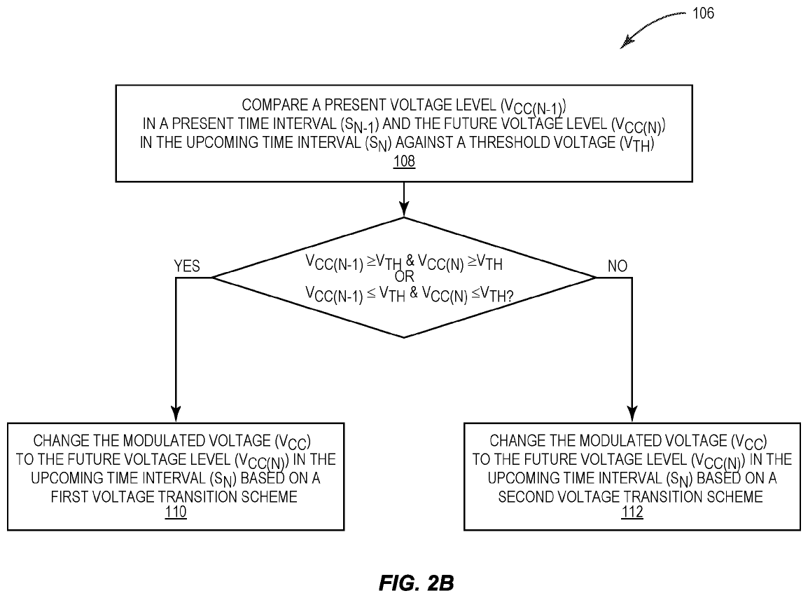

The PMIC 12 can be configured to change the modulated voltage V_{CC} from the present voltage level V_{CC(N-1)} to the future voltage level V_{CC(N)} based on a process. In this regard, FIG. 2A is a flowchart of an exemplary process 100 that can be employed by the PMIC 12 in FIG. 1 to change the modulated voltage V_{CC}.

Herein, the control circuit 24 receives the modulated target voltage V_{TGT} that indicates the modulated voltage V_{CC} needs to transition from the present voltage level V_{CC(N-1)} in the present time interval S_{N-1} among the time intervals S_{N-1}, S_{N} to the future voltage level V_{CC(N)} in the upcoming time interval S_{N} immediately succeeding the present time interval S_{N-1} among the time intervals S_{N-1}, S_{N} (step 102). Accordingly, the control circuit 24 can control the voltage processing circuit 22 to change the modulated voltage V_{CC} from the present voltage level V_{CC(N-1)} to the future voltage level V_{CC(N)} based on one of a first voltage transition scheme and a second voltage transition scheme (step 104).

In an embodiment, the control circuit 24 can determine whether the modulated voltage V_{CC} should be changed according to the first voltage transition scheme or the second voltage transition scheme in accordance with a process. In this regard, FIG. 2B is a flowchart of an exemplary process 106 whereby the PMIC 12 in FIG. 1 can determine whether to change the modulated voltage V_{CC} based on the first voltage transition scheme or the second voltage transition scheme.

Herein, the control circuit 24 compares both the present voltage level V_{CC(N-1)} and the future voltage level V_{CC(N)} against a threshold voltage V_{TH} (step 108). When the present voltage level V_{CC(N-1)} and the future voltage level V_{CC(N)} are both higher than or equal to the threshold voltage V_{TH} (V_{CC(N-1)}≥V_{TH} and V_{CC(N)}≥V_{TH}), or when the present voltage level V_{CC(N-1)} and the future voltage level V_{CC(N)} are both lower than or equal to the threshold voltage V_{TH} (V_{CC(N-1)}≤V_{TH} and V_{CC(N)}≤V_{TH}), the control circuit 24 determines to change the modulated voltage V_{CC} to the future voltage level V_{CC(N)} in the upcoming time interval S_{N} based on the first voltage transition scheme (step 110). Otherwise, the control circuit 24 determines to change the modulated voltage V_{CC} to the future voltage level V_{CC(N)} in the upcoming time interval S_{N} based on the second voltage transition scheme (step 112). Notably, both the first voltage transition scheme and the second voltage transition scheme are so determined to ensure that the PMIC 12 can change the modulated voltage V_{CC} from the present voltage level V_{CC(N-1)} to the future voltage level V_{CC(N)} within a very short switching interval (e.g., <20 nanoseconds).

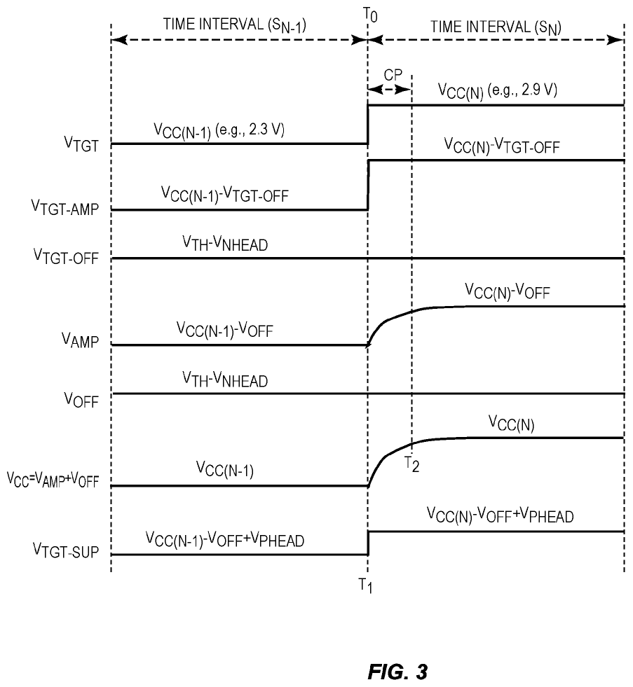

With reference back to FIG. 1, the voltage processing circuit 22 is configured to generate the modulated voltage V_{CC} at the voltage levels V_{CC(N-1)}, V_{CC(N)} in the time intervals S_{N-1}, S_{N}, respectively. As further described in FIGS. 3-7, the control circuit 24 is configured to control the voltage processing circuit 22 to change the modulated voltage V_{CC} from the present voltage level V_{CC(N-1)} to the future voltage level V_{CC(N)} based on the first voltage transition scheme or the second voltage transition scheme, as determined based on the process 100 of FIG. 2.

In an embodiment, the voltage processing circuit 22 includes a voltage amplifier 28 (denoted as “VA”), an offset circuit 30, a switcher circuit 32, and a supply voltage circuit 34. The voltage amplifier 28 is coupled to an input 36 of the offset circuit 30 and the offset circuit 30 is coupled to the voltage output 14. In the context of the present disclosure, the power amplifier circuit 16 is assumed to have a much higher bandwidth than that of the offset circuit 30.

Specifically, the voltage amplifier 28 is configured to generate a modulated initial voltage V_{AMP} based on an amplifier target voltage V_{TGT-AMP} and a supply voltage V_{SUP}. The supply voltage circuit 34 is configured to generate the supply voltage V_{SUP} based on a supply target voltage V_{TGT-SUP} and provide the supply voltage V_{SUP} to the voltage amplifier 28. According to various embodiments described herein, the control circuit 24 is configured to generate the amplifier target voltage V_{TGT-AMP} and the supply target voltage V_{TGT-SUP} based on the modulated target voltage V_{TGT} and in accordance with a determined one of the first voltage transition scheme and the second voltage transition scheme.

Herein, the offset circuit 30 includes an offset capacitor C_{OFF} and a bypass switch S_{BYP}. The offset capacitor C_{OFF} is coupled between the input 36 and the voltage output 14, and the bypass switch S_{BYP} is coupled between the input 36 and a ground (GND). The offset capacitor C_{OFF} may be charged or discharged to provide the modulated offset voltage V_{OFF} between the voltage amplifier 28 and the voltage output 14. As a result, the offset circuit 30 can raise the modulated initial voltage V_{AMP} by the modulated offset voltage V_{OFF} to thereby generate the modulated voltage V_{CC} at the voltage output 14 (V_{CC}=V_{AMP}+V_{OFF}).

The switcher circuit 32 includes a multi-level charge pump (MCP) 38. The MCP 38, which may be a direct current (DC)-DC buck-boost converter, is configured to generate a low-frequency voltage V_{DC} (e.g., DC voltage) based on a battery voltage V_{BAT}. Specifically, the MCP 38 may operate in a buck mode to generate the low-frequency voltage V_{DC} at 0×V_{BAT} or 1×V_{BAT}, or in a boost mode to generate the low-frequency voltage V_{DC} at 2×V_{BAT}. The MCP 38 may be configured to toggle between the buck mode and the boost mode based on a particular duty cycle (e.g., 20%@0×V_{BAT}, 30%@1×V_{BAT}, and 50%@2×V_{BAT}). As such, the MCP 38 may be controlled to generate the low-frequency voltage V_{DC} at a desired level.

In an embodiment, the control circuit 24 may be further configured to generate an offset target voltage V_{TGT-OFF} based on the modulated target voltage V_{TGT} and in accordance with the determined one of the first voltage transition scheme and the second voltage transition scheme. The offset target voltage V_{TGT-OFF} may indicate the future voltage level V_{CC(N)} of the modulated voltage V_{CC}. Accordingly, the MCP 38 may determine and operate based on a corresponding duty cycle to generate the low-frequency voltage V_{DC} at the desired level as indicated by the offset target voltage V_{TGT-OFF}.

The switcher circuit 32 also includes a power inductor L_{P}. The power inductor L_{P} is coupled between the MCP 38 and the voltage output 14 and is configured to induce a low-frequency current I_{DC} (e.g., a DC current) based on the low-frequency voltage V_{DC}. Understandably, the low-frequency current I_{DC} may be induced as a function of the low-frequency voltage V_{DC} and an inductance of the power inductor L_{P}. Accordingly, the control circuit 24 may further change the low-frequency current I_{DC} based on the offset target voltage V_{TGT-OFF}.

When operating under the first voltage transition scheme, the PMIC 12 can change the modulated voltage V_{CC} from the present voltage level V_{CC(N-1)} to the future voltage level V_{CC(N)} by keeping the offset voltage V_{OFF} constant and changing the modulated initial voltage V_{AMP}. Understandably, by keeping the offset voltage V_{OFF} constant, it is not necessary to charge or discharge the offset capacitor C_{OFF}. As a result, it is possible to prevent potential power loss resulted from charging or discharging the offset capacitor C_{OFF}.

FIG. 3 is a timing diagram providing an exemplary illustration of the PMIC 12 in FIG. 1 configured according to an embodiment of the present disclosure to increase the modulated voltage V_{CC} from the present voltage level V_{CC(N-1)} to the future voltage level V_{CC(N)} based on the first voltage transition scheme. Herein, the modulated target voltage V_{TGT} indicates that the modulated voltage V_{CC} will increase from the present voltage level V_{CC(N-1)} (e.g., 2.3 V) in the present time interval S_{N-1} to the future voltage level V_{CC(N)} (e.g., 2.9 V) in the upcoming time interval S_{N}.

As mentioned earlier, the control circuit 24 controls the voltage amplifier 28, the switcher circuit 32, and the supply voltage circuit 34 based on the amplifier target voltage V_{TGT-AMP}, the offset target voltage V_{TGT-OFF}, and the supply target voltage V_{TGT-SUP}, respectively. In a non-limiting example, the control circuit 24 sets the offset target voltage V_{TGT-OFF} to be equal to V_{TH}−V_{NHEAD} (a.k.a. “headroom voltage”). The control circuit 24 also sets the amplifier target voltage V_{TGT-AMP} to increase from a present level of V_{CC(N-1)}−V_{TGT-OFF} to a future level of V_{CC(N)}−V_{TGT-OFF}. The control circuit 24 further sets the supply target voltage V_{TGT-SUP} to increase from a present level of V_{CC(N-1)}−V_{OFF}+V_{PHEAD} (a.k.a. “floor voltage”) to a future level of V_{CC(N)}−V_{OFF}+V_{PHEAD}.

Notably in the present time interval S_{N-1}, the control circuit 24 has activated the voltage amplifier 28 to generate the modulated initial voltage V_{AMP} at the present level of V_{CC(N-1)}−V_{OFF}. Accordingly, at a start (e.g., at time T₁) of the upcoming time interval S_{N}, the voltage amplifier 28 remains active to start increasing the modulated initial voltage V_{AMP} to the future level of V_{CC(N)}−V_{OFF}. Concurrently, the supply voltage circuit 34 starts increasing the supply voltage V_{SUP} according to the supply target voltage V_{TGT-SUP} to ensure that the voltage amplifier 28 can operate at a higher efficiency to increase the modulated initial voltage V_{AMP} to the future level of V_{CC(N)}−V_{OFF} by the end of the CP (e.g., at time T₂) of the upcoming time interval S_{N}.

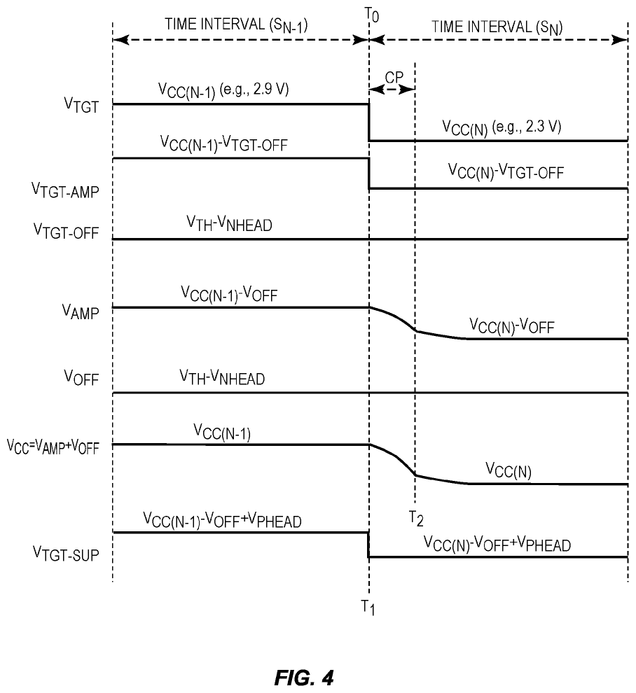

FIG. 4 is a timing diagram providing an exemplary illustration of the PMIC 12 in FIG. 1 configured according to an embodiment of the present disclosure to decrease the modulated voltage V_{CC} from the present voltage level V_{CC(N-1)} to the future voltage level V_{CC(N)} based on the first voltage transition scheme. Herein, the modulated target voltage V_{TGT} indicates that the modulated voltage V_{CC} will decrease from the present voltage level V_{CC(N-1)} (e.g., 2.9 V) in the present time interval S_{N-1} to the future voltage level V_{CC(N)} (e.g., 2.3 V) in the upcoming time interval S_{N}.

In a non-limiting example, the control circuit 24 sets the offset target voltage V_{TGT-OFF} to be equal to V_{TH}+V_{NHEAD} (a.k.a. “headroom voltage”). The control circuit 24 also sets the amplifier target voltage V_{TGT-AMP} to decrease from a present level of V_{CC(N-1)}−V_{TGT-OFF} to a future level of V_{CC(N)}−V_{TGT-OFF}. The control circuit 24 further sets the supply target voltage V_{TGT-SUP} to decrease from a present level of V_{CC(N-1)}−V_{OFF}+V_{PHEAD} (a.k.a. “floor voltage”) to a future level of V_{CC(N)}−V_{OFF}+V_{PHEAD}.

Notably in the present time interval S_{N-1}, the control circuit 24 has activated the voltage amplifier 28 to generate the modulated initial voltage V_{AMP} at the present level of V_{CC(N-1)}−V_{OFF}. Accordingly, at the start (e.g., at time T₁) of the upcoming time interval S_{N}, the voltage amplifier 28 remains active to start decreasing the modulated initial voltage V_{AMP} to the future level of V_{CC(N)}−V_{OFF}. Concurrently, the supply voltage circuit 34 starts decreasing the supply voltage V_{SUP} according to the supply target voltage V_{TGT-SUP} to ensure that the voltage amplifier 28 can operate at a higher efficiency to decrease the modulated initial voltage V_{AMP} to the future level of V_{CC(N)}−V_{OFF} by the end of the CP (e.g., at time T₂) of the upcoming time interval S_{N}.

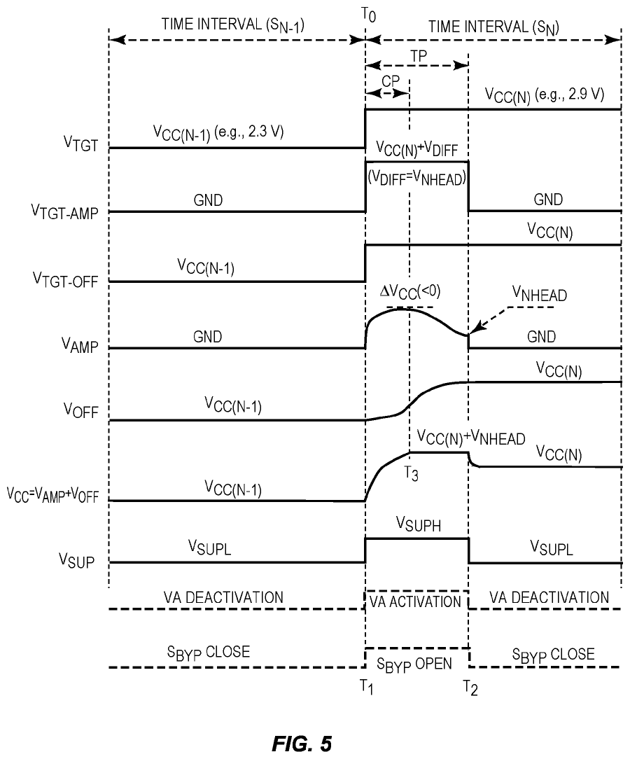

With reference back to FIG. 1, when operating under the second voltage transition scheme, the PMIC 12 can change the modulated voltage V_{CC} from the present voltage level V_{CC(N-1)} to the future voltage level V_{CC(N)} by adjusting the offset voltage V_{OFF}, in addition to using the voltage amplifier 28 to adjust the modulated initial voltage V_{AMP}. More specifically, the offset circuit 30 will cause the modulated voltage V_{CC} to change from the present voltage level V_{CC(N-1)} in the present time interval S_{N-1} to the future voltage level V_{CC(N)} in the upcoming time interval S_{N} during a transition interval (denoted as “TP” in FIGS. 5 to 7). Depending on whether the modulated voltage V_{CC} is increasing or decreasing from the present time interval S_{N-1} to the upcoming time interval S_{N}, the transition interval TP can be located either in the present time interval S_{N-1} or in the upcoming time interval S_{N} to ensure that the modulated voltage V_{CC} can reach the future voltage level V_{CC(N)} by the CP of the upcoming time interval S_{N}.

As further illustrated in FIGS. 5 to 7, while the modulated voltage V_{CC} transitions from the present voltage level V_{CC(N-1)} to the future voltage level V_{CC(N)} during the transition interval TP, the voltage amplifier 28 is activated at a start of the transition interval TP (denoted as “T₁”) and deactivated at an end of the transition interval TP (denoted as “T₂”) to ensure proper operation of the power amplifier circuit 16. Herein, the voltage amplifier 28 is configured to generate the modulated initial voltage V_{AMP} based on the amplifier target voltage V_{TGT-AMP} and the supply voltage V_{SUP}.

As discussed in detailed examples in FIGS. 5 to 7, the amplifier target voltage V_{TGT-AMP} is so determined to ensure that the voltage amplifier 28 can maintain the modulated initial voltage V_{AMP} at or above the headroom voltage V_{NHEAD}, which is greater than 0 V, at the end T₂ of the transition interval TP. As a result, the voltage amplifier 28 can maintain the modulated voltage V_{CC} at the present voltage level V_{CC(N-1)} and suppress a ripple in the modulated voltage V_{CC} during the transition interval TP to thereby ensure the proper operation of the power amplifier circuit 16 during the transition interval TP.

According to an embodiment of the present disclosure, the control circuit 24 can be configured to determine whether the transition interval TP should be within the present time interval S_{N-1} or the upcoming time interval S_{N} based on a differential ΔV_{CC} between the present voltage level V_{CC(N-1)} and the future voltage level V_{CC(N)} (ΔV_{CC}=V_{CC(N-1)}−V_{CC(N)}. Understandably, the differential ΔV_{CC} will be positive when the present voltage level V_{CC(N-1)} is higher than the future voltage level V_{CC(N)} or negative when the present voltage level V_{CC(N-1)} is lower than the future voltage level V_{CC(N)}. Accordingly, the control circuit 24 can control the offset circuit 30 (e.g., via a control signal 40) during the transition interval TP.

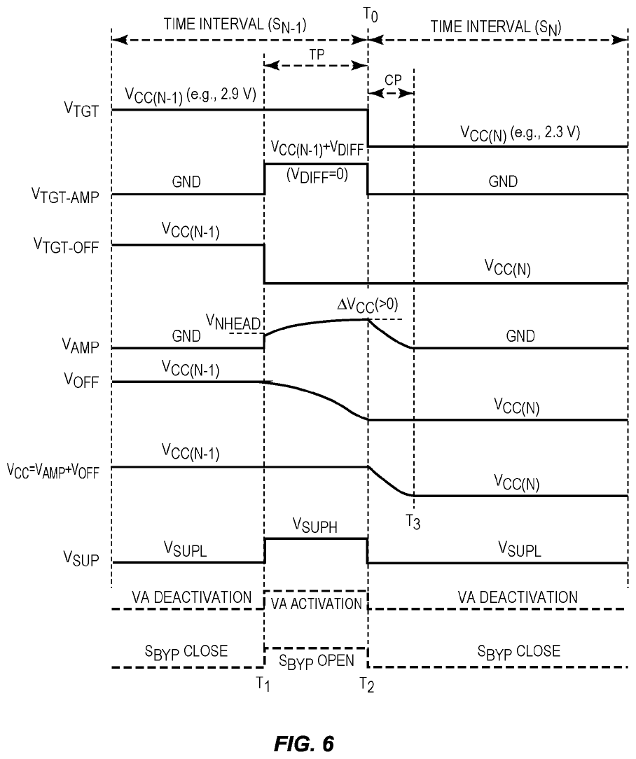

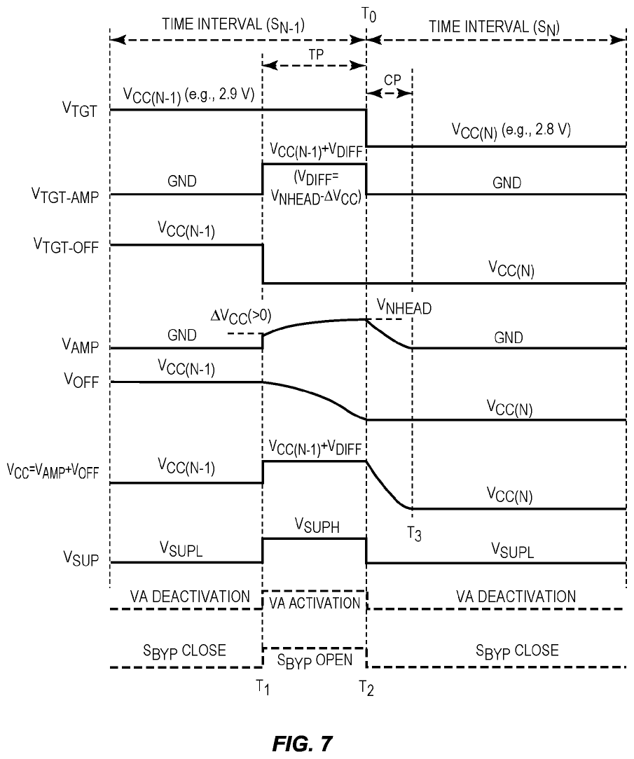

The control circuit 24 may also be configured to determine the amplifier target voltage V_{TGT-AMP} based on the determined differential ΔV_{CC}. When the future voltage level V_{CC(N)} is higher than the present voltage level V_{CC(N-1)}, as illustrated in FIG. 5, the amplifier target voltage V_{TGT-AMP} is equal to a sum of the future voltage level V_{CC(N)} and a markup voltage (denoted as “V_{DIFF}”), as shown in equation (Eq. 1) below. In contrast, when the future voltage level V_{CC(N)} is lower than the present voltage level V_{CC(N-1)}, as illustrated in FIGS. 6 and 7, the amplifier target voltage V_{TGT-AMP} is equal to a sum of the present voltage level V_{CC(N-1)} and the markup voltage V_{DIFF}, as shown in equation (Eq. 2) below.

$${V}_{TGT - AMP} = {V}_{CC ( N )} + {V}_{DIFF} \qquad ( Eq . 1 )$$

$${V}_{TGT - AMP} = {V}_{CC ( N - 1 )} + {V}_{DIFF} \qquad ( Eq . 2 )$$

In the equations (Eq. 1 and Eq. 2), the markup voltage V_{DIFF} can be of different values depending on how the modulated voltage V_{CC} will change from the present time interval S_{N-1} to the upcoming time interval S_{N}. In this regard, by changing the amplifier target voltage V_{TGT-AMP} and, more specifically the markup voltage V_{DIFF}, the control circuit 24 can cause the voltage amplifier 28 to generate the modulated initial voltage V_{AMP} at appropriate levels during the transition interval TP to maintain proper operation of the power amplifier circuit 16.

The control circuit 24 may be further configured to activate the voltage amplifier 28 at the start T₁ of the transition interval TP and deactivate the voltage amplifier 28 at the end T₂ of the transition interval TP. By controlling the offset circuit 30 to change the modulated voltage V_{CC} and activating/deactivating the voltage amplifier 28 to ensure proper operation of the power amplifier circuit 16 during the transition interval TP, the PMIC 12 can switch the modulated voltage V_{CC} efficiently under the increasingly stringent switching time requirements (e.g., <20 ns).

In one operating scenario under the second voltage transition scheme, the modulated voltage V_{CC} is set to increase from the present voltage level V_{CC(N-1)} in the present time interval S_{N-1} to the future voltage level V_{CC(N)} in the upcoming time interval S_{N} (V_{CC(N-1)}<V_{CC(N)}. In this regard, the control circuit 24 will set the offset target voltage V_{TGT-OFF} to the future voltage level V_{CC(N)} of the modulated voltage V_{CC} to cause the low-frequency current I_{DC} to be generated at a desired amount to thereby charge the offset capacitor C_{OFF} to the future voltage level V_{CC(N)}.

The control circuit 24 will open the bypass switch S_{BYP} and activate the voltage amplifier 28 at the start of the transition interval TP to generate the amplifier target voltage V_{TGT-AMP} at a level higher than the future voltage level V_{CC(N)} such that a current I_{TRAN} can flow from the MCP 38 through the offset capacitor C_{OFF} and sink in the voltage amplifier 28. As a result, the current I_{TRAN} will gradually charge the offset capacitor C_{OFF} to the future voltage level V_{CC(N)} during the transition interval TP. When the offset capacitor C_{OFF} is charged up to the future voltage level V_{CC(N)} at the end of the transition interval TP, the control circuit 24 deactivates the voltage amplifier 28 and closes the bypass switch S_{BYP}. Thereafter, the offset capacitor C_{OFF} and the MCP 38 will maintain the modulated voltage V_{CC} at the future voltage level V_{CC(N)} in the remainder of the upcoming time interval S_{N}.

The operating scenario described above can be graphically illustrated in FIG. 5. FIG. 5 is a timing diagram providing an exemplary illustration of the PMIC 12 in FIG. 1 configured according to an embodiment of the present disclosure to increase the modulated voltage V_{CC} from the present voltage level V_{CC(N-1)} to the future voltage level V_{CC(N)} based on the second voltage transition scheme.

As illustrated, the transition interval TP falls completely within the upcoming time interval S_{N}, wherein the start T₁ of the transition interval TP aligned with a boundary T₀ (a.k.a. a starting time of the CP in the upcoming time interval S_{N}) between the present time interval S_{N-1} and the upcoming time interval S_{N}, and the end T₂ of the transition interval TP comes after time T₃ (a.k.a. an ending time of the CP in the upcoming time interval S_{N}). Understandably, the CP is typically much shorter than the transition interval TP. Herein, the modulated target voltage V_{TGT} indicates that the modulated voltage V_{CC} will increase from the present voltage level V_{CC(N-1)} (e.g., 2.3 V) in the present time interval S_{N-1} to the future voltage level V_{CC(N)} (e.g., 2.9 V) in the upcoming time interval S_{N}. Accordingly, the control circuit 24 determines the offset target voltage V_{TGT-OFF} to be equal to the future voltage level V_{CC(N)} at the start of the transition interval TP.

As for the amplifier target voltage V_{TGT-AMP}, the control circuit 24 is configured to set the markup voltage V_{DIFF} in the equation (Eq. 1) to be equal to the headroom voltage V_{NHEAD} (V_{TGT-AMP}=V_{CC(N)}+V_{NHEAD}). At time T₁, the control circuit 24 opens the bypass switch S_{BYP} and activates the voltage amplifier 28. Accordingly, the voltage amplifier 28 will generate the modulated initial voltage V_{AMP} at the input 36 in accordance with the amplifier target voltage V_{TGT-AMP}. In a non-limiting example, the voltage amplifier 28 can quickly drive the modulated initial voltage V_{AMP} from a GND level to the differential ΔV_{CC} (ΔV_{CC}<0) at time T₃ to help stabilize the modulated voltage V_{CC} during the transition interval TP. Thereafter, the voltage amplifier 28 gradually decreases the modulated initial voltage V_{AMP} to the headroom voltage V_{NHEAD} at time T₂.

Starting at time T₁, the offset capacitor C_{OFF} is gradually charged up to reach the future voltage level V_{CC(N)} at time T₂. Accordingly, at time T₂, the control circuit 24 closes the bypass switch S_{BYP} and deactivates the voltage amplifier 28 to let the modulated initial voltage V_{AMP} return to the GND level. The modulated voltage V_{CC}, which equals a sum of the modulated initial voltage V_{AMP} and the offset voltage V_{OFF}, will settle at the future voltage level V_{CC(N)} at time T₃. Notably, since the voltage amplifier 28 maintains the modulated initial voltage V_{AMP} at or above the headroom voltage V_{NHEAD} while the bypass switch S_{BYP} is toggled, the modulated voltage V_{CC} will not drop below the headroom voltage V_{NHEAD}, thus ensuring proper operation of the power amplifier circuit 16.

With reference back to FIG. 1, in another operating scenario under the second voltage transition scheme, the modulated voltage V_{CC} is set to decrease from the present voltage level V_{CC(N-1)} in the present time interval S_{N-1} to the future voltage level V_{CC(N)} in the upcoming time interval S_{N} (V_{CC(N-1)}>V_{CC(N)}). In this regard, the control circuit 24 will set the offset target voltage V_{TGT-OFF} to the future voltage level V_{CC(N)} of the modulated voltage V_{CC} to cause the low-frequency current I_{DC} to be generated at a desired amount to thereby cause the offset capacitor C_{OFF} to be discharged to the future voltage level V_{CC(N)}.

The control circuit 24 will open the bypass switch S_{BYP} and activate the voltage amplifier 28 at the start of the transition interval TP to generate the amplifier target voltage V_{TGT-AMP} at the present voltage level V_{CC(N-1)} such that the current I_{TRAN} can flow from the voltage amplifier 28 through the offset capacitor C_{OFF} and return to the MCP 38 and/or the power amplifier circuit 16. As a result, the offset capacitor C_{OFF} will be gradually discharged to the future voltage level V_{CC(N)} during the transition interval TP. When the offset capacitor C_{OFF} is discharged to the future voltage level V_{CC(N)} at the end of the transition interval TP, the control circuit 24 deactivates the voltage amplifier 28 and closes the bypass switch S_{BYP}. Thereafter, the offset capacitor C_{OFF} and the MCP 38 will maintain the modulated voltage V_{CC} at the future voltage level V_{CC(N)} in the remainder of the upcoming time interval S_{N}.

The operating scenario described above can be graphically illustrated in FIGS. 6 and 7. FIG. 6 is a timing diagram providing an exemplary illustration of the PMIC 12 in FIG. 1 configured according to an embodiment of the present disclosure to decrease the modulated voltage V_{CC} from the present voltage level V_{CC(N-1)} to the future voltage level V_{CC(N)} based on the second voltage transition scheme. More specifically, FIG. 6 illustrates a situation where the headroom voltage V_{NHEAD} (e.g., 0.4 V) is lower than the differential ΔV_{CC} (e.g., 0.6 V) between the present voltage level V_{CC(N-1)} and the future voltage level V_{CC(N)} (V_{NHEAD}<ΔV_{CC}).

As illustrated, the transition interval TP falls completely within the present time interval S_{N-1}, wherein the start T₁ of the transition interval TP begins prior to a boundary T₀ between the present time interval S_{N-1} and the upcoming time interval S_{N}, and the end T₂ of the transition interval TP is aligned with the boundary T₀ (a.k.a. a starting time of the CP in the upcoming time interval S_{N}). Understandably, the CP is typically much shorter than the transition interval TP. Herein, the modulated target voltage V_{TGT} indicates that the modulated voltage V_{CC} will decrease from the present voltage level V_{CC(N-1)} (e.g., 2.9 V) in the present time interval S_{N-1} to the future voltage level V_{CC(N)} (e.g., 2.3 V) in the upcoming time interval S_{N}. Accordingly, the control circuit 24 determines the offset target voltage V_{TGT-OFF} to be equal to the future voltage level V_{CC(N)} at the start of the transition interval TP.

As for the amplifier target voltage V_{TGT-AMP}, the control circuit 24 is configured to set the markup voltage V_{DIFF} in the equation (Eq. 2) to 0 V (V_{TGT-AMP}=V_{CC(N-1)}+0). At time T₁, the control circuit 24 opens the bypass switch S_{BYP} and activates the voltage amplifier 28. Accordingly, the voltage amplifier 28 will generate the modulated initial voltage V_{AMP} at the input 36 in accordance with the amplifier target voltage V_{TGT-AMP}. In a non-limiting example, the voltage amplifier 28 can instantly drive the modulated initial voltage V_{AMP} from a GND level to the headroom voltage V_{NHEAD} at time T₁. Thereafter, the voltage amplifier 28 will continue to drive the modulated initial voltage V_{AMP} up to the voltage differential ΔV_{CC} at time T₂.

Starting at time T₁, the offset capacitor C_{OFF} is gradually discharged to reach the future voltage level V_{CC(N)} at time T₂. Accordingly, at time T₂, the control circuit 24 closes the bypass switch S_{BYP} and deactivates the voltage amplifier 28 to let the modulated initial voltage V_{AMP} return to the GND level at time T₃. The modulated voltage V_{CC}, which equals a sum of the modulated initial voltage V_{AMP} and the offset voltage V_{OFF}, will settle at the future voltage level V_{CC(N)} at time T₃. Notably, since the voltage amplifier 28 maintains the modulated initial voltage V_{AMP} at or above the headroom voltage V_{NHEAD} while the bypass switch S_{BYP} is toggled, the modulated voltage V_{CC} will not drop below the headroom voltage V_{NHEAD}, thus ensuring proper operation of the power amplifier circuit 16.

FIG. 7 is a timing diagram providing an exemplary illustration of the PMIC 12 in FIG. 1 configured according to another embodiment of the present disclosure to decrease the modulated voltage V_{CC} from the present voltage level V_{CC(N-1)} to the future voltage level V_{CC(N)} based on the second voltage transition scheme. More specifically, FIG. 7 illustrates a situation where the headroom voltage V_{NHEAD} (e.g., 0.4 V) is higher than or equal to the differential ΔV_{CC} (e.g., 0.1 V) between the present voltage level V_{CC(N-1)} and the future voltage level V_{CC(N)} (V_{NHEAD}≥ΔV_{CC}).

As illustrated, the transition interval TP falls completely within the present time interval S_{N-1}, wherein the start T₁ of the transition interval TP begins prior to a boundary T₀ between the present time interval S_{N-1} and the upcoming time interval S_{N}, and the end T₂ of the transition interval TP is aligned with the boundary T₀ (a.k.a. a starting time of the CP in the upcoming time interval S_{N}). Understandably, the CP is typically much shorter than the transition interval TP. Herein, the modulated target voltage V_{TGT} indicates that the modulated voltage V_{CC} will decrease from the present voltage level V_{CC(N-1)} (e.g., 2.9 V) in the present time interval S_{N-1} to the future voltage level V_{CC(N)} (e.g., 2.8 V) in the upcoming time interval S_{N}. Accordingly, the control circuit 24 determines the offset target voltage V_{TGT-OFF} to be equal to the future voltage level V_{CC(N)} at the start of the transition interval TP.

As for the amplifier target voltage V_{TGT-AMP}, the control circuit 24 is configured to set the markup voltage V_{DIFF} in the equation (Eq. 2) to equal the headroom voltage V_{NHEAD} minus the differential ΔV_{CC} between the present voltage level V_{CC(N-1)} and the future voltage level V_{CC(N)} (V_{TGT-AMP}=V_{CC(N-1)}+V_{NHEAD}−ΔV_{CC}). At time T₁, the control circuit 24 opens the bypass switch S_{BYP} and activates the voltage amplifier 28. Accordingly, the voltage amplifier 28 will generate the modulated initial voltage V_{AMP} at the input 36 in accordance with the amplifier target voltage V_{TGT-AMP}. In a non-limiting example, the voltage amplifier 28 can instantly drive the modulated initial voltage V_{AMP} from a GND level to the differential ΔV_{CC} at time T₁. Thereafter, the voltage amplifier 28 will continue to drive the modulated initial voltage V_{AMP} up to the headroom voltage V_{NHEAD} at time T₂.

Starting at time T₁, the offset capacitor C_{OFF} is gradually discharged to reach the future voltage level V_{CC(N)} at time T₂. Accordingly, at time T₂, the control circuit 24 closes the bypass switch S_{BYP} and deactivates the voltage amplifier 28 to let the modulated initial voltage V_{AMP} return to the GND level at time T₃. The modulated voltage V_{CC}, which equals a sum of the modulated initial voltage V_{AMP} and the offset voltage V_{OFF}, will settle at the future voltage level V_{CC(N)} at time T₃. Notably, since the voltage amplifier 28 maintains the modulated initial voltage V_{AMP} at or above the headroom voltage V_{NHEAD} while the bypass switch S_{BYP} is toggled, the modulated voltage V_{CC} will not drop below the headroom voltage V_{NHEAD}, thus ensuring proper operation of the power amplifier circuit 16.

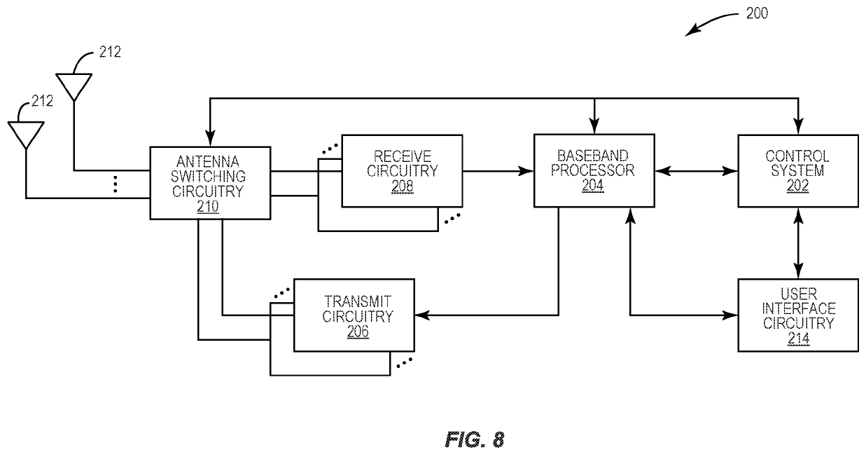

The wireless communication circuit 10 of FIG. 1 can be provided in a user element to change the modulated voltage V_{CC} according to embodiments described above. In this regard, FIG. 8 is a schematic diagram of an exemplary user element 200 wherein the wireless communication circuit 10 of FIG. 1 can be provided.

Herein, the user element 200 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 200 will generally include a control system 202, a baseband processor 204, transmit circuitry 206, receive circuitry 208, antenna switching circuitry 210, multiple antennas 212, and user interface circuitry 214. In a non-limiting example, the control system 202 can be a field-programmable gate array (FPGA), as an example. In this regard, the control system 202 can include at least a microprocessor(s), an embedded memory circuit(s), and a communication bus interface(s). The receive circuitry 208 receives radio frequency signals via the antennas 212 and through the antenna switching circuitry 210 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 204 processes the digitized received signal to extract the information or data bits conveyed in the received signal. This processing typically comprises demodulation, decoding, and error correction operations, as will be discussed in greater detail below. The baseband processor 204 is generally implemented in one or more digital signal processors (DSPs) and application specific integrated circuits (ASICs).

For transmission, the baseband processor 204 receives digitized data, which may represent voice, data, or control information, from the control system 202, which it encodes for transmission. The encoded data is output to the transmit circuitry 206, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 212 through the antenna switching circuitry 210. The multiple antennas 212 and the replicated transmit and receive circuitries 206, 208 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

1. A power management integrated circuit (PMIC) comprising:
a voltage output that outputs a modulated voltage to a power amplifier circuit for amplifying a radio frequency, RF, signal modulated in a plurality of time intervals;
a voltage processing circuit configured to generate the modulated voltage at a respective voltage level in each of the plurality of time intervals; and
a control circuit configured to:
receive a modulated target voltage indicating that the modulated voltage needs to transition from a present voltage level in a present time interval among the plurality of time intervals to a future voltage level in an upcoming time interval immediately succeeding the present time interval among the plurality of time intervals; and
control the voltage processing circuit to change the modulated voltage from the present voltage level to the future voltage level based on one of a first voltage transition scheme and a second voltage transition scheme.

2. The PMIC of claim 1, wherein the control circuit is further configured to:
control the voltage processing circuit to change the modulated voltage from the present voltage level to the future voltage level based on the first voltage transition scheme when any one of the following conditions is met:
the present voltage level and the future voltage level are both higher than or equal to a threshold voltage; and
the present voltage level and the future voltage level are both lower than or equal to the threshold voltage; and
control the voltage processing circuit to change the modulated voltage from the present voltage level to the future voltage level based on the second voltage transition scheme when any one of the following conditions is met:
the present voltage level is higher than the threshold voltage and the future voltage level is lower than the threshold voltage; and
the present voltage level is lower than the threshold voltage and the future voltage level is higher than the threshold voltage.

3. The PMIC of claim 1, wherein the voltage processing circuit comprises:
a voltage amplifier configured to generate a modulated initial voltage based on a supply voltage and the modulated target voltage;
an offset circuit coupled between the voltage amplifier and the voltage output and configured to raise the modulated initial voltage by a modulated offset voltage to generate the modulated voltage at the voltage output;
a switcher circuit configured to cause the offset circuit to provide the modulated offset voltage between the voltage amplifier and the voltage output; and
a supply voltage circuit configured to generate the supply voltage.

4. The PMIC of claim 3, wherein, in the first voltage transition scheme, the control circuit is further configured to:
determine that the future voltage level of the modulated voltage is higher than the present voltage level of the modulated voltage;
control the offset circuit to maintain the modulated offset voltage at a constant voltage level between the present time interval and the upcoming time interval;
control the supply voltage circuit to increase the supply voltage at a start of the upcoming time interval; and
control the voltage amplifier to increase the modulated initial voltage at the start of the upcoming time interval based on the increased supply voltage.

5. The PMIC of claim 3, wherein, in the first voltage transition scheme, the control circuit is further configured to:
determine that the future voltage level of the modulated voltage is lower than the present voltage level of the modulated voltage;
control the offset circuit to maintain the modulated offset voltage at a constant voltage level between the present time interval and the upcoming time interval;
control the supply voltage circuit to decrease the supply voltage at a start of the upcoming time interval; and
control the voltage amplifier to decrease the modulated initial voltage at the start of the upcoming time interval based on the decreased supply voltage.

6. The PMIC of claim 3, wherein, in the second voltage transition scheme, the control circuit is further configured to:
determine a start and an end of a transition interval based on the present voltage level and the future voltage level of the modulated voltage;
determine an amplifier target voltage to be equal to a sum of the future voltage level and a markup voltage;
activate the voltage amplifier at the start of the transition interval; and
deactivate the voltage amplifier at the end of the transition interval.

7. The PMIC of claim 6, wherein the control circuit is further configured to:
determine that the future voltage level of the modulated voltage is higher than the present voltage level of the modulated voltage;
determine the start of the transition interval to be at a boundary between the present time interval and the upcoming time interval;
determine the end of the transition interval to be later than the boundary between the present time interval and the upcoming time interval;
determine the markup voltage to be equal to a headroom voltage; and
cause the offset circuit to increase the modulated voltage from the present voltage level to the future voltage level by the end of the transition interval.

8. The PMIC of claim 6, wherein the control circuit is further configured to:
determine that the future voltage level of the modulated voltage is lower than the present voltage level of the modulated voltage and a headroom voltage is lower than a differential between the present voltage level and the future voltage level;
determine the start of the transition interval to be earlier than a boundary between the present time interval and the upcoming time interval;
determine the end of the transition interval to be at the boundary between the present time interval and the upcoming time interval;
determine the markup voltage to be equal to zero; and
cause the offset circuit to decrease the modulated voltage from the present voltage level to the future voltage level by the end of the transition interval.

9. The PMIC of claim 6, wherein the control circuit is further configured to:
determine that the future voltage level of the modulated voltage is lower than the present voltage level of the modulated voltage and a headroom voltage is higher than or equal to a differential between the present voltage level and the future voltage level;
determine the start of the transition interval to be earlier than a boundary between the present time interval and the upcoming time interval;
determine the end of the transition interval to be at the boundary between the present time interval and the upcoming time interval;
determine the markup voltage to be equal to the headroom voltage subtracted by the differential between the present voltage level and the future voltage level; and
cause the offset circuit to decrease the modulated voltage from the present voltage level to the future voltage level by the end of the transition interval.

10. The PMIC of claim 1, wherein each of the plurality of time intervals corresponds to an orthogonal frequency division multiplexing (OFDM) symbol.

11. A method for switching a modulated voltage comprising:
receiving a modulated target voltage indicating that the modulated voltage needs to transition from a present voltage level in a present time interval among a plurality of time intervals to a future voltage level in an upcoming time interval immediately succeeding the present time interval among the plurality of time intervals; and
changing the modulated voltage from the present voltage level to the future voltage level based on one of a first voltage transition scheme and a second voltage transition scheme.

12. The method of claim 11, further comprising:
changing the modulated voltage from the present voltage level to the future voltage level based on the first voltage transition scheme when any one of the following conditions is met:
the present voltage level and the future voltage level are both higher than or equal to a threshold voltage; and
the present voltage level and the future voltage level are both lower than or equal to the threshold voltage; and
changing the modulated voltage from the present voltage level to the future voltage level based on the second voltage transition scheme when any one of the following conditions is met:
the present voltage level is higher than the threshold voltage and the future voltage level is lower than the threshold voltage; and
the present voltage level is lower than the threshold voltage and the future voltage level is higher than the threshold voltage.

13. The method of claim 11, further comprising:
generating a modulated initial voltage based on a supply voltage and the modulated target voltage; and
raising the modulated initial voltage by a modulated offset voltage to generate the modulated voltage.

14. The method of claim 13, further comprising:
determining that the future voltage level of the modulated voltage is higher than the present voltage level of the modulated voltage;
maintaining the modulated offset voltage at a constant voltage level between the present time interval and the upcoming time interval;
increasing the supply voltage at a start of the upcoming time interval; and
increasing the modulated initial voltage at the start of the upcoming time interval based on the increased supply voltage.

15. The method of claim 13, further comprising:
determining that the future voltage level of the modulated voltage is lower than the present voltage level of the modulated voltage;
maintaining the modulated offset voltage at a constant voltage level between the present time interval and the upcoming time interval;
decreasing the supply voltage at a start of the upcoming time interval; and
decreasing the modulated initial voltage at the start of the upcoming time interval based on the decreased supply voltage.

16. The method of claim 13, further comprising:
determining a start and an end of a transition interval based on the present voltage level and the future voltage level of the modulated voltage;
determining an amplifier target voltage to be equal to a sum of the future voltage level and a markup voltage;
generating the modulated initial voltage at the start of the transition interval; and
stop generating the modulated initial voltage at the end of the transition interval.

17. The method of claim 16, further comprising:
determining that the future voltage level of the modulated voltage is higher than the present voltage level of the modulated voltage;
determining the start of the transition interval to be at a boundary between the present time interval and the upcoming time interval;
determining the end of the transition interval to be later than the boundary between the present time interval and the upcoming time interval;
determining the markup voltage to be equal to a headroom voltage; and
increasing the modulated voltage from the present voltage level to the future voltage level by the end of the transition interval.

18. The method of claim 16, further comprising:
determining that the future voltage level of the modulated voltage is lower than the present voltage level of the modulated voltage and a headroom voltage is lower than a differential between the present voltage level and the future voltage level;
determining the start of the transition interval to be earlier than a boundary between the present time interval and the upcoming time interval;
determining the end of the transition interval to be at the boundary between the present time interval and the upcoming time interval;
determining the markup voltage to be equal to zero; and
decreasing the modulated voltage from the present voltage level to the future voltage level by the end of the transition interval.

19. The method of claim 16, further comprising:
determining that the future voltage level of the modulated voltage is lower than the present voltage level of the modulated voltage and a headroom voltage is higher than or equal to a differential between the present voltage level and the future voltage level;
determining the start of the transition interval to be earlier than a boundary between the present time interval and the upcoming time interval;
determining the end of the transition interval to be at the boundary between the present time interval and the upcoming time interval;
determining the markup voltage to be equal to the headroom voltage subtracted by the differential between the present voltage level and the future voltage level; and
decreasing the modulated voltage from the present voltage level to the future voltage level by the end of the transition interval.

20. The method of claim 11, wherein each of the plurality of time intervals corresponds to an orthogonal frequency division multiplexing (OFDM) symbol.
